(19) United States
(12) Patent Application Publication
(10) Pub. No.: US 2009/0306918 A1
(43) Pub. Date: Dec. 10, 2009

(54) Office Id Remote with Oscillating Circuit

(75) Inventors: Paul Denis Driscoll, Newport (GB); Carl Linsey Nurton, Nelson (GB); Mark Samuel Govier, Cardiff (GB)

Correspondence Address: PILLSBURY WINTHROP SHAW PITTMAN LLP, P.O BOX 10500, McLean, VA, 22102, US

(73) Assignee: TEMPO EUROPE LIMITED, LONDON (GB)

(21) Appl. No.: 12/308,212

(22) PCT Filed: Jun. 4, 2007
(86) PCT No.: PCT/GB2007/002046

§ 371 Date: Aug. 10, 2009

(30) Foreign Application Priority Data
Jun. 9, 2006 (GB) 0611413.6

(51) Int. Cl. G06F 19/00; G01R 19/00; G01R 13/00

(52) U.S. Cl. 702/67; 324/66

(57) ABSTRACT

An office ID remote that creates an oscillating waveform with a predetermined characteristic on a conductor found in a cable is provided. This characteristic is typically the rate of repetition of the waveform that can be compared to a table of rates of repetition stored in a main test unit that correlates each rate of repetition to a particular office ID remote. This allows the identity of the cable to be ascertained.

### BACKGROUND OF THE INVENTION

Wiremapping devices are used in the Voice, Data, and Video industry to diagnose the termination and integrity of cables between different locations. These devices usually include a main test unit and at least one remote unit, which are connected at different ends of a single cable using RJ11/12 jacks for telephone cables, RJ45 jacks for communication cables, and F connectors for coaxial cables. Once this physical connection has been made, these devices begin a series of test protocols to detect a number of problems associated with the particular type of cable that is being tested, whether it is a coaxial, telephone, or communications cable.

Coaxial cables are typically tested for opens and shorts. If there are open or short circuits, then time domain reflectometry technology (TDR) is frequently used to determine the distance from the main test unit to the fault so that a repair can be made. When a four twisted pair communications cable is being tested, the device usually detects opens, shorts, miswires, reversals, and split pairs as part of the wiremapping process. TDR technology is also used to indicate the location of any faults. In addition, an AC signal is sent down each twisted pair to determine if there are any split pairs. If the pair is properly terminated, then the phase differential of the signal as it passes through each wire of the pair cancels the signal out. If the pair is split, then the signal is not canceled out and can be detected.

In situations where more than one cable is terminated at a patch panel and it is unclear what the source of each of the cables is, additional remote units are provided for connection at the remote ends of the various cables to indicate to the main test unit which cable at the patch panel corresponds to which office cable. This function is often referred to as office ID function. Accomplishing the office ID function is the most complicated in a communications cable (such as a four twisted pair communications cable) application because this application requires a large number of identification tags as compared to the other two applications (i.e., open/shorts or split pairs). For example, a four twisted pair communications cable requires three different identification tags for three of the twisted pairs and another identification tag for the office ID for a remaining one of the twisted pairs. This may require 11 different electrical identification tags, e.g., the three different identification tags and eight different potential electrical identification tags utilized for the Office ID function. If polarity for each pair is also tested, then double the number of electrical identifications tags may be necessary. Finding an economical and accurate method for establishing this many identification tags can be a problem.

One method for office identification includes providing a main unit with a microcontroller and a plurality of remote units that also have microcontrollers. The remote units send bits of information via their microcontrollers to the main unit to perform the office ID function. The advantage of this technique is that it can handle a vast number of remote identifications with great accuracy. The disadvantage is that this is relatively expensive and may require a higher current requirement in the remote circuitry than is preferable

Another technique that is used for the Office ID function is to provide a main unit with a microcontroller and a DC power supply and a plurality of remotes, which use networks that have resistors and capacitors of different values in conjunction with a diode. Each RC combination creates a different time constant, which creates an identification tag for that particular twisted pair. In operation, the DC power supply sends current to one of these resistor, capacitor, and diode combinations in the remote unit, and providing that the polarity of the twisted pair is correct, the capacitor begins to charge. The time that is necessary for the capacitor to charge is measured by the microcontroller of the main unit and compared to a stored table to see with which time constant that pair matches up. Of course, another RC/diode combination is required to perform the office ID function as well. This may take a large number of different resistor, capacitor, and diode combinations to provide the necessary number of identification tags. For example, 11 remote units may be necessary when utilizing the RC/diode combinations.

This method has two disadvantages. First, it is difficult to obtain enough resistors and capacitors of different values to obtain this many identification tags, e.g., over 11 or 22 identification tags depending on the embodiment. Also, it is difficult to have a large number of significantly different resistors and capacitors, because the resistors and capacitors have standard values with tolerances. Due to the tolerances inherent in the standard resistors and capacitors, it is difficult to have predictable and stable values for the RC constants. Second, measuring time constants can be slow and less accurate than desirable, creating the possibility of improper matching of time constants to those stored in the data table of the main test unit. This, of course, can lead to incorrect diagnoses and hinder any troubleshooting that is necessary.

Accordingly, there exists a need for a method and apparatus for creating an identification tag for wire that is less complex, less costly, and more reliable than is currently available. This will make it easier to provide a remote unit that can perform both the wiremapping and office ID functions in an economical manner.

### SUMMARY OF THE INVENTION

The present invention includes a method for identifying a cable that has at least two conductors comprising the following steps. First, a current signal or a voltage signal is supplied to one of the conductors. The current signal or voltage signal is transformed into an oscillating wavefonm that has a predetermined characteristic. The value of the characteristic of the wavefonm is measured. The value of the characteristic of the waveform is compared to values stored in a table, which correlates a cable identity with the value of the characteristic of the waveform. The identity of the cable is then communicated to a user. Illustratively, the transforming of the current may include creating a waveform with a predetermined rate of repetition, while the step of measuring the waveform may include determining that rate of repetition.

In the present invention, a system for performing the invention includes a main test unit, a remote unit, and a cable. A main test unit includes a power supply, a memory, a comparison circuit, and a measurement circuit or measurement logic. A remote unit includes an oscillator circuit or oscillator logic. The cable utilized in the system includes at least two conductors that connect or couple the remote unit to the main test unit so that a current signal or a voltage signal can be conveyed to the remote unit from the main test unit through one of the conductors. The oscillator circuit in the remote unit receives the current signal (or the voltage signal) and creates an oscillating waveform having a predetermined characteristic utilizing the received current signal or voltage signal. The oscillating waveform is then conveyed back to the main test unit through another conductor of the at least two conductors and the main test unit measures the value of the predetermined characteristic. The main unit compares the measured value of the characteristic to those stored in the table in the memory of the main test unit to ascertain from which remote unit the oscillating signal was sent. Illustratively, this characteristic may be the rate of repetition of the wavefonm or some other identifying trait. Once the match has been made between the cable and the measured characteristic of the oscillating waveform, the cable's identity is communicated to the user.

In another embodiment, the main unit may include a current source that supplies current to a cable. The remote unit may include an oscillator circuit that creates an oscillating waveform of a particular profile on the cable. The main unit includes measurement circuit (or measurement logic) that can measure a particular trait of the waveform and memory housing stored values, wherein the main unit compares the measured particular trait to stored trait values in the memory, where the trait values also include a cable identification. The result of the comparison is a match between the trait values stored in memory and the measured trait, which then provides the cable identification.

### BRIEF DESCRIPTION OF THE DRAWINGS

FIG. 1(a) illustrates a block diagram of a remote identification (ID) system according to an embodiment of the present invention;

FIG. 1(b) is a schematic of the main test unit and remote unit of an embodiment of the invention;

FIG. 2 is a schematic of the remote unit of an embodiment of the invention;

FIG. 3 is a table showing values of resistors utilized in the schematic of FIG. 2 that create the appropriate rates of repetition for eight office ID remote units according to an embodiment of the invention; and

FIG. 4 is a flowchart illustrating a method of remote cable identification according to an embodiment of the invention.

### DETAILED DESCRIPTION OF THE INVENTION

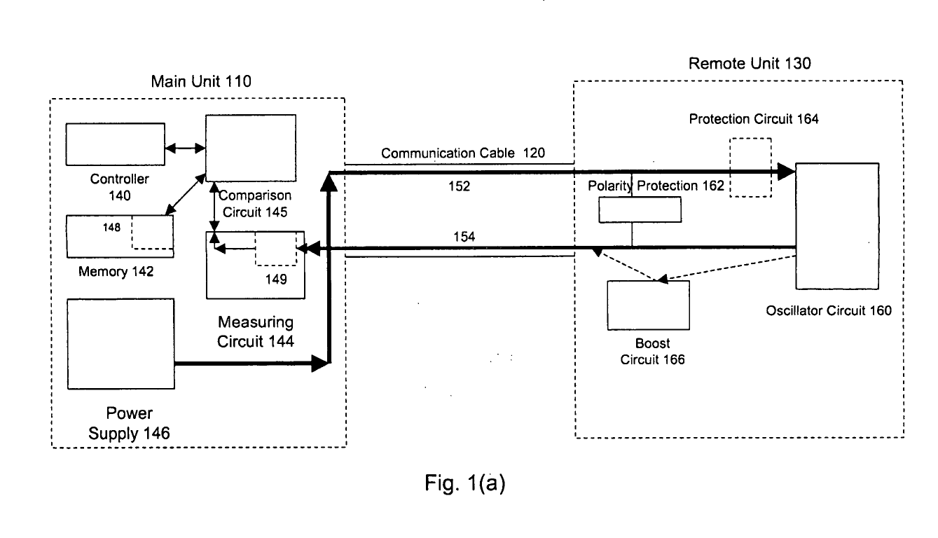

FIG. 1(a) illustrates a block diagram of a cable remote identification system according to an embodiment of the invention. The cable remote identification system 100 includes a main unit 110, a cable 120, and a remote unit 130. In an embodiment of the invention, the main unit 110 may include a controller 140, memory 142, measurement circuitry 144, a comparison circuit 145, and a DC power source 146. In an embodiment of the invention, the measurement circuitry 144 and the comparison circuit 145 may be a measurement module 144 or a comparison module 145, respectively, because the function of the circuitry may be implemented in software.

In an embodiment of the invention, a microcontroller 140 may execute instructions to operate the main test unit. In an embodiment of the invention, the microcontroller 140 may execute instructions to cause the comparison module 145 in order to compare the measured value to values in a table. In an embodiment of the invention, the microcontroller 140 may include the memory 142 and the measurement circuitry 144. In an embodiment of the invention, the microcontroller 140 may include the memory, the measurement circuitry 144, and the comparison circuit 145. In an alternative embodiment of the invention, the microcontroller 140, the memory 142, and the measurement circuit 144, and the comparison circuit 145 may be separate devices and may be coupled or connected together. In an embodiment of the invention, the memory 142 may include a table 148. The table 148 may include values representing characteristics of a waveform and a cable identification associated with the waveform characteristics. In an embodiment of the invention, the measurement circuitry 144 may include a comparator 149. The comparator 149 may be utilized to increase the resolution of the oscillating waveform. In an embodiment of the invention, the comparator 149 may be a voltage level comparator that is used to detect incoming pulses from the remote unit 130. The comparison circuit 145 may receive the signal from the measurement circuit 144, wherein the measurement circuit determines the operating characteristic of the received signal from the remote unit 130. In an embodiment of the invention, the microcontroller 140 may execute instructions to cause the comparison circuit 145 to compare the operating characteristic of the received signal with the table of waveform characteristics stored in the memory 142. If a match is made between the operating characteristic of the received signal and one of the waveform characteristics in memory 142, the microcontroller 140 may generate a signal or message identifying which of the cables identifications (e.g., cable electrical identifications) has a corresponding operating characteristic to the received operating characteristic.

In an embodiment of the invention, the cable 120 may include a plurality of conductors. In FIG. 1(a), two conductors 152 and 154 are illustrated, although a cable may have a plurality of conductors. In an embodiment of the invention, a signal transmitted from the main unit to the remote unit 130 utilizes a first conductor 152. The signal transmitted from the remote unit 130 to the main unit 120 may utilize a second conductor 154. Alternatively, the signal may be transmitted from the remote unit 130 to main unit 110 on the first conductor 152. In an embodiment of the invention, the cable 120 may include a number of twisted pairs, each of which have at least two conductors.

In an embodiment of the invention, the remote unit 130 includes a oscillator circuit 160. In an embodiment of invention, the remote unit 130 may include a polarity protection circuit 162. In an embodiment of the invention, the polarity protection circuit 162 may be placed in parallel with the conductors with the cable 120, e.g., conductors 152 and 154, in order to protect the oscillator circuit 160 if a polarity of the current signal or the voltage signal is switched. In an embodiment of the invention, the remote unit 130 may include a current or voltage protection circuit 164 to protect the oscillator circuit 160 from damage if a higher than expected value of a voltage is received from the main unit. The current or voltage protection circuit 164 may limit a value of the current signal or the voltage signal which is supplied to the oscillator circuit 160 in the remote unit 130 in order to protect the oscillator circuit 160. In an embodiment of the invention, the remote unit 130 may include a boost circuit 166. The boost circuit 166 may receive the oscillating waveform from the oscillator circuit 160, boost an amplitude of the oscillation waveform or signal to generate an amplified oscillation waveform, and transmit the oscillation waveform via a conductor on the cable 120 to the main unit 110.

In an embodiment of the invention, the remote unit may include a plurality of RC constant circuits along with the oscillator circuit 160. In this embodiment of the invention, the remote unit 130 may be utilized for identifying four cable pairs in a four twisted-pair communication cable. Three cable pairs may be identified by three RC constant circuits and one cable pair may be identified by the oscillator circuit 160. In this embodiment of the invention, the remote unit 130 could also include the current or voltage protection circuit 164, the boost circuit 166, or the polarity protection circuit 162.

FIG. 1(b) shows the wiring schematic of the main test unit 10 and remote unit 12 according to an embodiment of the present invention. The driver circuit in the main test unit 10 includes a five-volt power source 14 that simulates the output of a pair of tri-state buffers that are used during various testing protocols of the apparatus. During most of the wiremapping process, this power source 14 supplies DC current with resistor 16 and resistor 18 providing the paths to get this current to the line or conductor being tested. When a fault location is being determined using TDR technology, capacitors 20, 22 provide a bypass for the high frequency pulses while resistors 24, 26 make sure that the total impedance for the driver circuit is a specific value, e.g., one hundred ohms. Once any current, whether DC or AC, exits the main test unit 10, the current passes through the cable being tested whose resistance is represented by resistor 28 and is usually negligible for short runs. It should also be noted that resistor 30 and diode 32 branch off on one side of the power source 14 while resistor 34 and diode 36 branch off on the other side of the power source 14. These components provide protection for the circuitry of the main test unit 10 if any voltages that exceed the power supply rails or thresholds of the driver circuit are applied to the main test unit 10. In an embodiment of the invention, these components, e.g., resistor 30, diode 32, resistor 34, and diode 36 may be referred to as a main unit voltage protection circuit.

When the main test unit 10 is in the office ID mode, the power source 14 may supply five volts of DC power of either polarity which results in a current being supplied and transmitted from the main test unit 10 to the cable. After the current has passed through the cable being tested, it enters the remote unit 12 and encounters a diode 38 that is connected in parallel to the incoming and outgoing conductors of the cable being tested. If the voltage applied to the remote unit 12 is reversed, then the diode 38 short circuits the incoming current and prevents damage to the rest of the circuitry found in the remote unit 12. In an embodiment of the invention, this protection circuit may be referred to as a polarity protection circuit 162. It is preferred to use a diode in parallel rather than in series because the diode 38 would create too great a voltage drop if the diode were placed in series with the incoming current. Diode 38 also provides the additional function of indicating whether a DC current is present during the wiremapping process.

Assuming that the polarity of the power source 14 is correct during the office ID function, the incoming current from the main unit 10 encounters a protection circuit, e.g., a depletion mode MOSFET 40 and a resistor 25, that limit the amount of current that is supplied to the remote unit 12 to a specified current, e.g., one milliamp. The MOSFET 40 and the resistor 25 may be referred to as a current protection circuit 164. The current protection circuit 164 ensures that the circuitry of the remote unit 12 will not be damaged if a voltage that is greater than intended is applied to it. For example, the voltages for which the circuits in the remote unit 12 is protected may be, for example, 48 V DC up to 120 V AC. In an embodiment of the invention, the circuits may operated reliably with voltages of between 2.0 and 15 Volts.

The current is then collected by a capacitor 44, which acts a reservoir capacitor. In an embodiment of the invention, the output of the capacitor 44 may be limited by diode 46 to 3.3 volts DC. The voltage from the capacitor 44 is applied to an oscillation circuit 160, which, for example, may be a relaxation oscillator circuit. In this embodiment of the invention, the relaxation oscillation circuit may formed by a first resistor 48, a first transistor 50, a second transistor 52, a second resistor 54, a third resistor 56, and a second capacitor 58. Once the supply voltage from the capacitor 44 has increased to a sufficient level, the oscillation circuit may begin to oscillate. In the embodiment of the invention illustrated in FIG. 1(b), the second capacitor 58 and the second resistor 54 are mostly responsible for determining the time constant of this circuit. Pulses generated from the oscillation circuit are coupled to the base of a third transistor 60 by way of a fourth resistor 62 and a third capacitor 64, which ensure that the pulses of the oscillating wavefonm are of short duration. The third transistor 60 repeatedly short-circuits the incoming current to increase the current the pulses of the oscillating waveform. The third transistor 60 is ensuring that the oscillating waveform is coupled to the conductor or line that transmits the oscillating wavefonm back to the main test unit 110. In an embodiment of the invention, narrow pulses need to be utilized because the short-circuiting of the third transistor 60 is interrupting the power flow to the remote unit 130. In an embodiment of the invention, a continuous wavefonm may also be utilized to transmit information back to the main test unit 10. In this embodiment of the invention, the main test unit 10 can more easily measure the rate of repetition of the oscillating waveform produced by the oscillating circuit. If necessary, the main test unit 10 may reverse the polarity of the power supply 14 to enable the oscillating circuit to produce the necessary rate of repetition.

Once the oscillating waveform signal has been generated, the remote unit 12 transmits the oscillating wavefonm signal back to the main test unit 10 where the measurement circuit 144 is located. In the embodiment of the invention illustrated in FIG. 1(a), the measurement circuit 144 may include two voltage or potential dividers. A first voltage or potential divider is formed by resistors 66 and 68 and is coupled or connected to an analog to digital converter 74. The second divider is formed by resistors 70 and 72 and is coupled or connected to a comparator 76 with a processor controlled threshold. The comparator 76 increases the resolution of the oscillating waveform signal so that its rate of repetition can be more easily and accurately obtained. The measurement circuit 144 receives the oscillating waveform signal and measures a value of a characteristic of the oscillating waveform signal. Illustratively, the measurement circuit 144 may measure a rate of repetition of the received oscillating waveform signal.

The measured value of the received oscillating waveform signal is compared to values stored in memory 142 of the main unit. In an embodiment of the invention, a comparison circuit or module 145 may compare the measured value of the oscillating waveform signal to the values stored in memory 142. In an embodiment of the invention, the microcontroller 140 may include instructions causing the comparison circuit or module 145 to compare the measured value of the oscillating waveform signal to the values stored in memory 142. The memory 142 includes values for representative characteristics and corresponding cable electrical identification which would produce the characteristics. This comparison determines from which remote unit 12 the signal was sent. In an embodiment of the invention, the comparison circuit or module 145 determines an exact match between the measured value and a table entry. In an embodiment of the invention, the comparison circuit or module 145 determines a closest match between the measured value and a table entry in the memory 142. The cable identification is then known. The cable identification is then communicated to a user. In an embodiment of the invention, the measurement circuitry 144 and memory 142 are included as part of a microcontroller within the main test unit 10. In an embodiment of the invention, the measurement circuitry 144 and the comparison circuitry 145 are included as part of the microcontroller 140 in the main test unit.

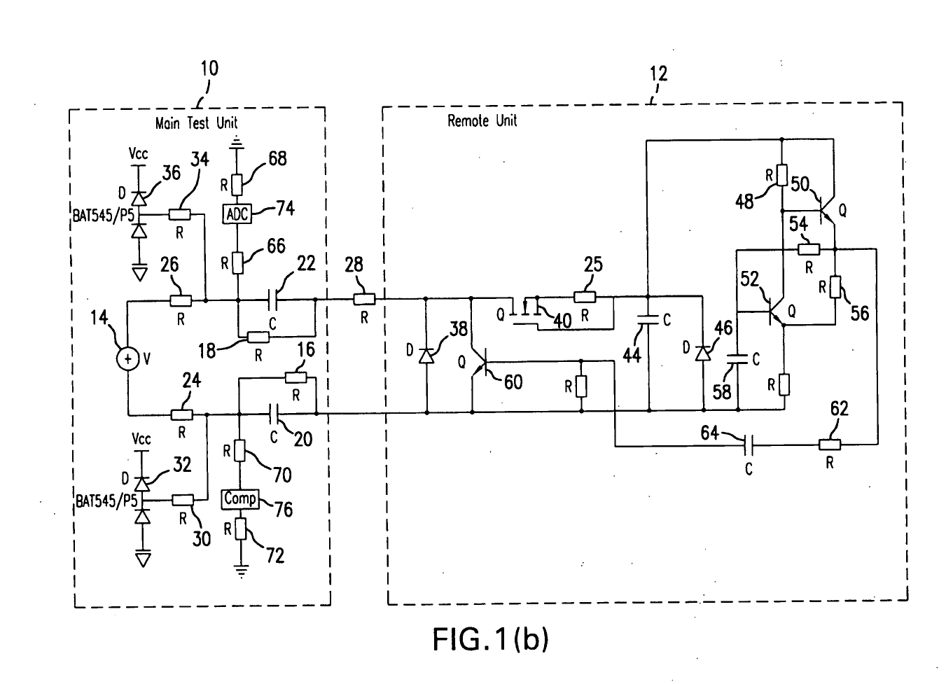

FIG. 2 illustrates a schematic of a second remote unit according to an embodiment of the present invention. The remote unit 12 receives power from the main test unit 10. The main test unit 10 for this embodiment is similar to the main unit for the embodiment described above in FIG. 1(a). Illustratively, the remote unit 12 receives power from the main test unit 10 by a nine pin connector 78 for a four twisted pair communications cable and a two pin F connector 80 for a coaxial cable. Both the wiremapping and office ID functions are performed on the pair formed by the third and sixth conductors of a communications cable using the same technique discussed above for FIG. 1(b) of the invention. However, in the embodiment of the invention illustrated in FIG. 2, the remote unit 12 utilizes a different oscillation circuit as compared to FIG. 1(b). In lieu of a relaxation oscillator circuit, this embodiment of the invention utilizes a standard 555 integrated circuit chip 86 in conjunction with resistors 82 and 84 to create the appropriate rate of repetition of the oscillating waveform. In this embodiment of the invention, the value of resistors 82 and 84 may determine this rate of repetition. In all other ways, the circuitry of the remote unit 12 in this embodiment, illustrated in FIG. 2, is similar to the remote unit 12 of the first embodiment, illustrated in FIG. 1(b). An accuracy of the oscillating waveform provided by this embodiment is greater than that provided by the relaxation oscillator circuit of the first embodiment (FIG. 1(b)) and may be preferential for use in many situations. This same technique may be used for the office ID function for any coaxial cable being tested. When performing the wiremapping for the other three pairs of conductors of a communications cable, the prior technique of using a network of capacitors, resistors, and diodes may be employed.

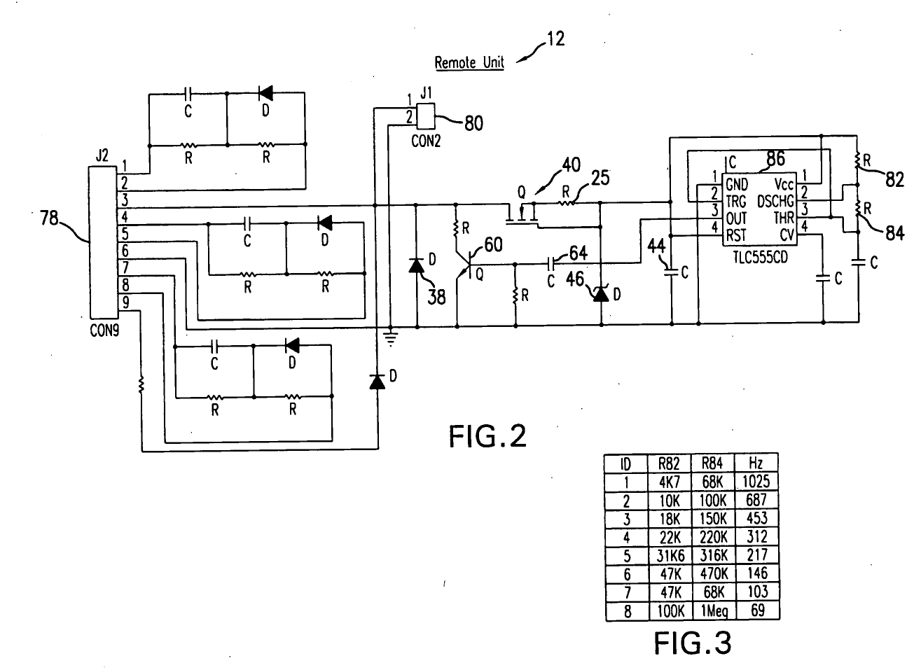

FIG. 3 illustrates a table in a memory of a main test unit according to an embodiment of the present invention. The table illustrated in FIG. 3 includes values of resistors 82 and 84 (for the embodiment of the invention illustrated in FIG. 2) that provide eight different oscillating waveforms with eight different rates of repetitions so that eight office ID remotes can be utilized to identify up to eight different cables. A similar table may be stored in memory 142 for the embodiment of the invention illustrated in FIG. 1(b) where the table may include values for the second capacitor 58 and the second resistor 54. In the embodiment of the invention illustrated in FIG. 2, each office ID remote includes the appropriate values of resistors 82 and 84 that produce a rate of repetition that matches the table shown in FIG. 3 and the office ID and frequency correlation is stored in the memory of the main test unit 10.

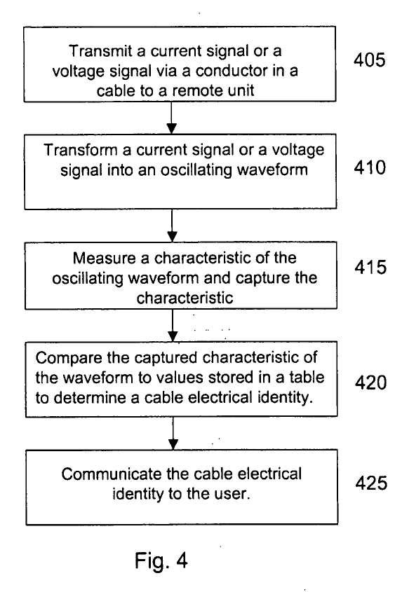

FIG. 4 illustrates a flowchart of performing remote identification of a cable according to an embodiment of the invention. In an embodiment of the invention, a power supply in a main unit transmits 405 a current signal or a voltage signal via a cable to a remote unit. In an embodiment of the invention, the cable has a plurality of conductors and in this embodiment, the main unit transmits the current or voltage signal via one conductor (or a first conductor) of the plurality of conductors in the cable. The remote unit receives the current signal. After receipt of the current signal, an oscillating circuit in the remote unit transforms 410 the current signal into an oscillating waveform or oscillating waveform signal. The remote unit then transfers the oscillating waveform signal to the main unit via the cable. In an embodiment of the invention, a second conductor of the cable is utilized to transfer the oscillating waveform signal to the main test unit. In an embodiment of the invention, the second conductor is different from the first conductor.

The main test unit receives the oscillating waveform signal from the cable. A measurement circuit in the main test unit measures 415 a characteristic of the oscillating waveform and captures the characteristic. In an embodiment of the invention, the characteristic may be a rate of repetition of the waveform.

After measuring a value of the characteristic of the oscillating waveform, the main test unit may compare 420 the captured or measured characteristic of the oscillating waveform to values stored in a table in a memory to determine a cable identity. Each entry in the table in memory may include a representative characteristic and a cable that corresponds to or is associated with the characteristic.

Once the cable characteristic is identified, the cable identity is communicated 425 to a user. The communication may be made by a display on the main test unit. Alternatively, the communication may be made by the main test unit communicating to a computing device or portable computing device. The computing device or the portable device may be separate from the main test unit. In an embodiment of the invention, the communication may take place via wireless communication or wired communication.

As can be seen, the preferred embodiment of the present invention provides a way to accurately perform the office ID function using the rate of repetition of an oscillating waveform created by an integrated circuit chip. However, it is clear that those skilled in the art may devise various modifications of the present invention without departing from the spirit and scope of the attached claims.

While the above description refers to particular embodiments of the present invention, it will be understood to those of ordinary skill in the art that modifications may be made without departing from the spirit thereof. The accompanying claims are intended to cover any such modifications as would fall within the true scope and spirit of the present invention.

The presently disclosed embodiments are therefore to be considered in all respects as illustrative and not restrictive; the scope of the invention being indicated by the appended claims, rather than the foregoing description. All changes that come within the meaning and range of equivalency of the claims are therefore intended to be embraced therein.

What is claimed is:

1. A system to apply an electrical identification tag to a cable, comprising:
a main test unit, the main test unit including a power supply, a memory, and measurement circuit, the main test unit transmitting a current signal;
a remote unit, the remote unit including an oscillator circuit where the oscillator circuit is not included in a microcontroller, the remote unit receiving the current signal, transforming the current signal into a oscillating waveform having a predetermined characteristic, and transferring the oscillating waveform back to the main test unit; and
a cable, the cable including at least two conductors to connect the main test unit and the remote unit in order to transmit the current signal and the oscillating waveform inbetween, wherein the predetermined characteristic of the oscillating waveform is measured by said measurement circuit and compared to values stored in said memory to determine the electrical identification tag to be associated with said cable.

2. The system of claim 1, wherein the power supply of the main test unit is a DC power supply, the cable is a four twisted pair communications cable and at least one pair of the four twisted pair communications cable has an oscillating waveform applied thereto by the remote unit.

3. The system of claim 1 wherein the memory and measurement circuit of the main test unit are located in a microcontroller.

4. The system of claim 1, wherein the main test unit also includes a comparison circuit and the comparison circuit compares the measured predetermined characteristic of the oscillating waveform to the values stored in said memory to identify the electrical identification tag of the remote unit.

5. The system of claim 4, wherein the memory, the measurement circuit, and the comparison circuit are located in a microcontroller.

6. The system of claim 1, wherein the remote unit further includes a polarity protection circuit, the polarity protection circuit prevents damage to the oscillator circuit if a polarity of the current signal supplied to the remote unit is reversed.

7. The system of claim 6, wherein the polarity protection circuit is a diode and the diode is connected in parallel with the two conductors in the cable.

8. The system of claim 1, wherein the remote unit includes a current protection circuit, the current protection circuit limiting a value of current from the current signal to the oscillator circuit to a predetermined level to protect the oscillator circuit from damage if a higher than intended voltage is supplied to the remote unit.

9. The system of claim 8, wherein the current protection circuit is a depletion mode MOSFET located between the oscillator circuit and the incoming current signal.

10. The system of claim 1 wherein the oscillator circuit in the remote unit is a relaxation oscillator circuit including a network of resistors, capacitors, and transistors, the relaxation oscillator circuit creating the oscillating waveform having the predetermined characteristic, the predetermined characteristic being a predetermined rate of repetition.

11. The system of claim 1, wherein the remote unit further includes a boost circuit to boost an amplitude of the oscillating waveform in order to make the oscillating waveform more easily measured by the main test unit.

12. The system of claim 11, wherein the boost circuit is a transistor.

13. The system of claim 1, further including a plurality of remote units, each of the plurality of remote units having a oscillating waveform circuit that is capable of producing an oscillating waveform having a different rate of repetition than the first remote unit and each of the other plurality of remote units.

14. The system of claim 13 wherein the memory of the main test unit includes a table that correlates each of the plurality of remote units with the rate of repetition of the oscillating wavefonm that the individual remote unit generates.

15. The system of claim 13, wherein each of the plurality of remote units includes an oscillator circuit with an integrated circuit chip that is capable of producing an oscillating wavefonm having a unique predetermined characteristic.

16. The system of claim 15, wherein the measurement circuit in the main test unit includes a comparator for increasing a resolution of the oscillating waveform so that the unique predetermined characteristic of the oscillating waveform can be more accurately determined.

17. The system of claim 1, wherein the measurement circuit in the main unit includes a comparator for increasing the resolution of the oscillating waveform so that the predetermined characteristic of the oscillating wavefonm can be more accurately determined.

18. The system of claim 1 wherein the oscillator circuit includes a standard integrated circuit chip that generates an oscillating waveform having a predetermined rate of repetition.

19. The system of claim 18 wherein the remote unit further includes a transistor that boosts the amplitude of the oscillating waveform so that the oscillating waveform can be more easily measured by the main test unit.

20. The method of identifying a cable, the cable including at least two conductors, comprising:
supplying a current signal to a first conductor of the at least two conductors;
transforming said current signal into an oscillating waveform having a predetermined characteristic at a remote unit;
measuring a value of said predetermined characteristic of the oscillating waveform at a main test unit; and
comparing said value of the characteristic of the oscillating waveform to a table stored in a memory of the main test unit to correlate a cable electrical identity with the value of the characteristic of the oscillating waveform.

21. The method of claim 20, further including communicating the cable electrical identity to a user.

22. The method of claim 20, wherein transforming the current signal includes producing an oscillating waveform with a predetermined rate of repetition and said measuring of said characteristic includes determining a rate of repetition of the oscillating waveform.

23. A system to apply an electrical identification tag on a cable, comprising:
a current source in a main test unit to generate a current signal;
a cable to receive the current signal from the current source;
an oscillator circuit in a remote unit, the remote unit being connected to the cable, to receive the current signal supplied by the current source and to transform the current signal into an oscillating waveform having a predetermined characteristic;
a measurement circuit to measures a value of the predetermined characteristic of the oscillating waveform after the oscillating waveform has been transmitted from the remote unit to the main test unit; and
a memory, including a table stored with different values of the predetermined characteristic corresponding to different remote unit electrical identification tags, wherein the main test unit compares the measured value of the predetermined characteristic of the oscillating waveform to the different values of the predetermined characteristic in order to find a corresponding value within the table and determine a remote unit electrical identification tag for the cable.

24. A main test unit to apply an electrical identification tag to a cable, comprising:
a power supply to generate a current signal and to transmit the current signal to a cable which is connected to a remote unit;
a memory, the memory including a table, the table having a plurality of values of predetermined characteristics of oscillating waveforms corresponding to cable electrical identification tags;
a measurement circuit to receive an oscillating waveform having a predetermined characteristic from the remote unit, the remote unit having transformed the current signal into the oscillating waveform; and
a comparison circuit to compare the predetermined characteristic of the oscillating waveform to the plurality of values of predetermined characteristics stored in the table to determine a match to one of the remote unit identification tags.

25. The main test unit according to claim 24, further including a controller to communicate the matching remote unit identification tag by generating a message and the comparison circuit.

26. A program code-storage device, comprising:
a program code storage medium; and
program code stored on the program code storage medium, having instructions, which when executed cause a main test unit to:
generate a current signal;
supply the current signal to a first conductor in a cable that connects the main test unit to a remote unit;
receive an oscillating waveform from the remote unit, where the current signal was transformed into the oscillating waveform by the remote unit;
measure a value of a characteristic of the oscillating waveform; and
compare said value of the characteristic of the oscillating wavefonm to a table stored in a memory in the main test unit to correlate a remote unit electrical cable identity with the value of the characteristic of the oscillating waveform, the table including a plurality of values of characteristics and corresponding remote unit electrical cable identities.

27. A remote unit, comprising:
an input/output (I/O) terminal to receive a current signal from a main test unit;
a current protection circuit to limit an amplitude of the current signal to protect the remote unit from being exposed to a high voltage;
an oscillator circuit to receive the current signal and to transform the current signal into an oscillating waveform having a predetermined characteristic; and
a circuit to receive the oscillating wavefonm having the predetermined characteristic and to transfer the oscillating wavefonm to the I/O terminal for transmission to the main test unit.

28. The remote unit of claim 27, wherein the oscillator circuit is a relaxation oscillator circuit including a network of resistors, capacitors, and transistors.

29. The remote unit of claim 27, wherein the oscillator circuit is a standard integrated circuit chip that generates the oscillating waveform having the predetermined rate of repetition

30. The remote unit of claim 27, wherein the circuit is a transistor.

31. The remote unit of claim 27, further including a polarity protection circuit to prevent the current signal from damaging the remote unit if the current signal has reversed polarity.
